(19) United States
(12) Patent Application Publication
(10) Pub. No.: US 2009/0168379 A1
(43) Pub. Date: Jul. 2, 2009

(54) ELECTRONIC APPARATUS

(75) Inventors: Daisuke Maehara, Ome-shi (JP); Koichiro Takeguchi, Hachioji-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/203,818

(22) Filed: Sep. 3, 2008

(30) Foreign Application Priority Data
Dec. 27, 2007 (JP) 2007-338230

(51) Int. Cl. H05K 7/00

(52) U.S. Cl. 361/760

(57) ABSTRACT

According to one embodiment, an electronic apparatus includes: a polygonal printed circuit board provided with a cutout portion at least in a part, the cutout portion defined by at least a first edge and a second edge; and a first electronic component mounted on the printed circuit board; wherein the first electronic component is mounted at a position crossing a line defined by the first edge on the printed circuit board.

### CROSS-REFERENCE TO RELATED APPLICATIONS

This application is based upon and claims the benefit of priority from Japanese Patent Application No. 2007-338230, filed on Dec. 27, 2007, the entire contents of which are incorporated herein by reference.

### BACKGROUND

1. Field

One embodiment of the invention relates to a countermeasure art against deflection and warpage of a printed circuit board installed in a small-sized electronic apparatus and in particular to an electronic apparatus for making it possible to efficiently reinforce a printed circuit board.

2. Description of the Related Art

Hitherto, the slimming down and miniaturization of a portable personal computer and other small-sized electronic apparatuses have proceeded and usage of easily carrying out the electronic apparatuses has increased. However, as a casing of a small-sized electronic apparatus and a printed circuit board installed therein are also slimmed down, deflection or warpage occurs due to overload, etc., and the apparatus performance may be affected.

Hitherto, various printed circuit board reinforcing measures have been adopted. For example, an art has been proposed wherein a reinforcing member provided by bending sheet metal as angular U-shaped in cross section is fitted into a periphery of a printed circuit board with a spring property, thereby providing a warpage prevention structure of the printed circuit board (see JP-A-4-284692, for instance).

Described above in JP-A-4-284692 is the warpage prevention structure wherein a reinforcing member provided by bending sheet metal as angular U-shaped in cross section is fitted around a rectangular printed circuit board with a spring property, thereby providing the warpage of the printed circuit board and a structure wherein the sheet metal is attached to three edges of the rectangular printed circuit board and the printed circuit board has a connector on the remaining edge.

However, to provide a not rectangular but polygonal printed circuit board, for example, with such a reinforcing member, dedicated components to the polygonal printed circuit board is required and the number of components and a weight are increased. The art is hard to apply to an electronic apparatus including a certain shaped board having an area where the bending stress in a board thickness direction concentrates because of the difference of at least either of the board width and the length, such as the polygonal printed circuit board.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view showing a configuration of an electronic apparatus according to an embodiment of the invention;

FIG. 2 is an exemplary plan view of the printed circuit board shown in FIG. 1;

FIG. 3 is an exemplary side view of the printed circuit board viewed from direction III shown in FIG. 2;

FIG. 4 is an exemplary side view of the printed circuit board viewed from direction IV shown in FIG. 2;

FIG. 5 is an exemplary perspective view showing a printed circuit board according to another embodiment of the invention; and

FIG. 6 is an exemplary perspective view showing a printed circuit board according to still another embodiment of the invention.

### DETAILED DESCRIPTION

Various embodiments according to the invention will be described hereinafter with reference to the accompanying drawings. In general, according to one embodiment of the invention, an electronic apparatus includes: a polygonal printed circuit board provided with a cutout portion at least in a part, the cutout portion defined by at least a first edge and a second edge; and a first electronic component mounted on the printed circuit board; wherein the first electronic component is mounted at a position crossing a line defined by the first edge on the printed circuit board.

An embodiment of an electronic apparatus according to the invention will be discussed with reference to the accompanying drawings.

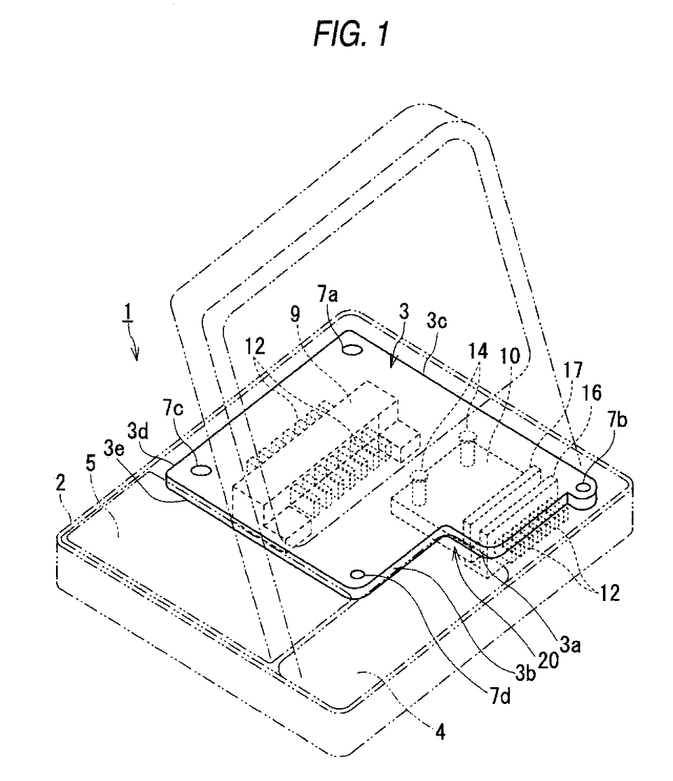

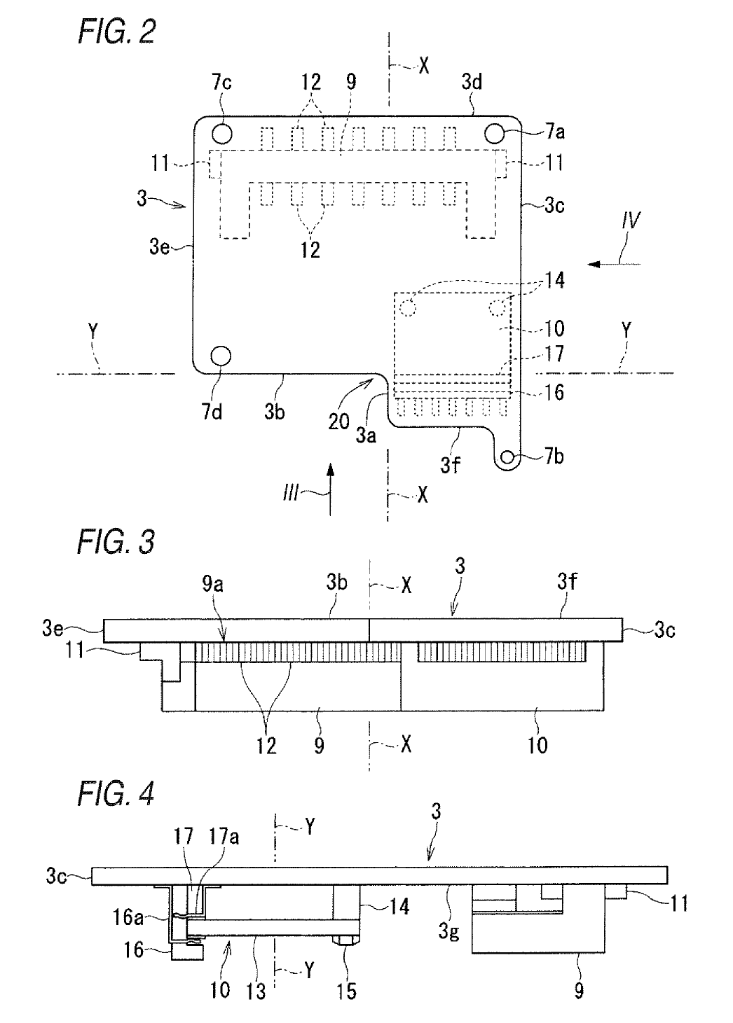

FIG. 1 is a perspective view to schematically show the main part of an electronic apparatus such as a portable personal computer incorporating a reinforcement structure against deflection, warpage, etc., of a printed circuit board, and FIG. 2 is a plan view of the printed circuit board shown in FIG. 1. FIG. 3 is a side view of the printed circuit board viewed from a direction indicated by arrow III shown in FIG. 2, and FIG. 4 is another side view of the printed circuit board viewed from a direction indicated by arrow IV shown in FIG. 2 (direction perpendicular to the direction indicated by arrow III).

As shown in FIG. 1, a polygonal printed circuit board 3 is installed in a casing 2 of an electronic apparatus 1 of the embodiment. The printed circuit board 3 is provided with a cutout portion 20 by cutting one edge of a quadrangular board like a letter L on the plan view over a given width and a given length. The cutout portion 20 is defined by a first edge 3a and a second edge 3b of the printed circuit board 3. The first edge 3a forming a part of the cutout portion 20 is shorter than a third edge 3c and a fifth edge 3e defining the outer periphery of the printed circuit board 3. On the other hand, the second edge 3b forming a part of the cutout portion 20 like the first edge 3a is shorter than a fourth edge 3d defining the outer periphery of the printed circuit board 3, but is longer than a sixth edge 3f.

The cutout portion 20 is a part of a battery housing area 4 of the casing 2, for example, and the area adjacent to the battery housing area 4 is a housing area 5 of a hard disk drive, etc.

Three corners other than the corner to which the cutout portion 20 belongs in the printed circuit board 3 are fixed to the casing 2 with fasteners 7a, 7b, 7c, and 7d of screws, etc. A connector 9 and a module board 10 are provided on a back 3g of the printed circuit board 3.

As shown in FIG. 2, the printed circuit board 3 is provided with the cutout portion 20, whereby a bending strength difference occurs between the area where the third edge 3c exists and the area where the fifth edge 3e exists with a line X-X as a boundary on the printed circuit board 3. Likewise, the printed circuit board 3 is provided with the cutout portion 20, whereby a bending strength difference occurs between the area where the fourth edge 3d exists and the area where the sixth edge 3f exists with a line Y-Y as a boundary on the printed circuit board 3. At this time, a stress concentrates on the line X-X and the line Y-Y as compared with other areas on the printed circuit board 3 because of the bending strength difference on the printed circuit board 3.

Then, in the embodiment, the connector 9 is placed on the line X-X on which a stress concentrates on the printed circuit board 3, and is joined to the printed circuit board 3. The connector 9 is placed crossing the line X-X on which a stress concentrates, whereby it is used as a reinforcement member against deflection and warpage of the printed circuit board so as to reinforce the printed circuit board 3 and lightening the bending stress.

The module 10 is placed on the line Y-Y on which a stress concentrates like the line X-X on the printed circuit board 3, and is joined to the printed circuit board 3. The module 10 is placed crossing the line Y-Y on which a stress concentrates, whereby it is used as a reinforcement member against deflection and warpage of the printed circuit board so as to reinforce the printed circuit board 3 and lighten the bending stress.

FIG. 3 is a side view showing a state in which the connector 9 and the module 10 are viewed from the direction indicated by the arrow III shown in FIG. 2; it shows a layout of the connector 9 and the module 10 relative to the printed circuit board 3.

The connector 9 includes a solder fixing terminal 11 provided in a side end part, signal connection terminals 12, and peripheral terminals (not shown) and a joint part 9a to the printed circuit board 3 is welded and joined roughly as a whole through the terminals. The printed circuit board 3 and the connector 9 are integrated into one by the welding, so that the strength against the bending of the printed circuit hoard 3 is still more enhanced. The connector 9 is provided with the signal connection terminals 12, as shown in FIGS. 1 to 3.

The connector 9 includes the solder fixing pad 11 provided in the side end part and a peripheral pad (not shown), and the joint part 9a to the printed circuit hoard 3 is welded and joined roughly as a whole through the pad. The printed circuit board 3 and the connector 9 are integrated into one by the welding, so that the strength against the bending of the printed circuit board 3 is still more enhanced. The connector 9 is provided with the signal connection terminals 12, as shown in FIGS. 1 to 3.

FIG. 4 is a side view showing a state in which the connector 9 and the module 10 are viewed from the direction indicated by the arrow IV shown in FIG. 2; it also shows the layout of the connector 9 and the module 10 relative to the printed circuit board 3.

As shown in FIG. 4, as the module 10, a module board 13 is placed at a distance from the printed circuit board 3. The module board 13 is supported by a hollow tubular metal spacer 14 joined to the printed circuit board 3, a screw member 15 screwed into the metal spacer 14, and housings 16 and 17 projected from the printed circuit board 3. The housings 16 and 17 include connection terminals 16a and 17a having a spring property and connect the printed circuit board 3 and the module board 13 by the connection terminals.

The described module 10 is not directly joined to the printed circuit board 3 unlike the connector 9. However, the module 10 is placed crossing the line Y-Y on which a stress concentrates through the metal spacer 14, the screw member 15, and the housings 16 and 17, whereby it can reinforce the printed circuit board 3. Accordingly, the module 10 functions as a reinforcement member against deflection and warpage of the printed circuit board 3 as it lightens the bending stress imposed on the printed circuit board 3.

As described above, in the embodiment, the connector 9 and the module 10 as the electronic components mounted on the printed circuit board 3 are placed at the positions crossing the lines on which a stress concentrates, whereby the connector 9 and the module 10 can be used as reinforcement members against deflection and warpage of the printed circuit board. Therefore, they can also be applied as the reinforcement members against deflection and warpage of the printed circuit board 3 to the configuration including an oddly shaped board having a part on which the bending stress in the board thickness direction concentrates because of the difference of the board width, the length, etc., a special component dedicated to reinforcement is not required, an increase in the weight of the electronic apparatus 1 can be prevented, and a large mount space and sheet metal are not required. Thus, the advantages of reducing the cost, improvement of applicability to a small-sized electronic apparatus, etc., are provided.

According to the embodiment, the connector 9 of the electronic component as the reinforcement member is joined and fixed to the board face containing the part of the printed circuit board 3 on which a stress concentrates, so that a large reinforcement effect can be provided. Particularly, the connector 9 includes the solder fixing terminal 11 and the joint strength can be enhanced by welding to the printed circuit board 3.

The module 10 used as the reinforcement member is not directly joined to the printed circuit board 3, but crosses the stress concentration point through the metal spacer 14, the screw member 15, the housings 16 and 17, and the connection terminals 16a and 17a and can reinforce the printed circuit board 3.

The shape of the printed circuit board 3 to which the invention is applied is not limited to that in the embodiment described above.

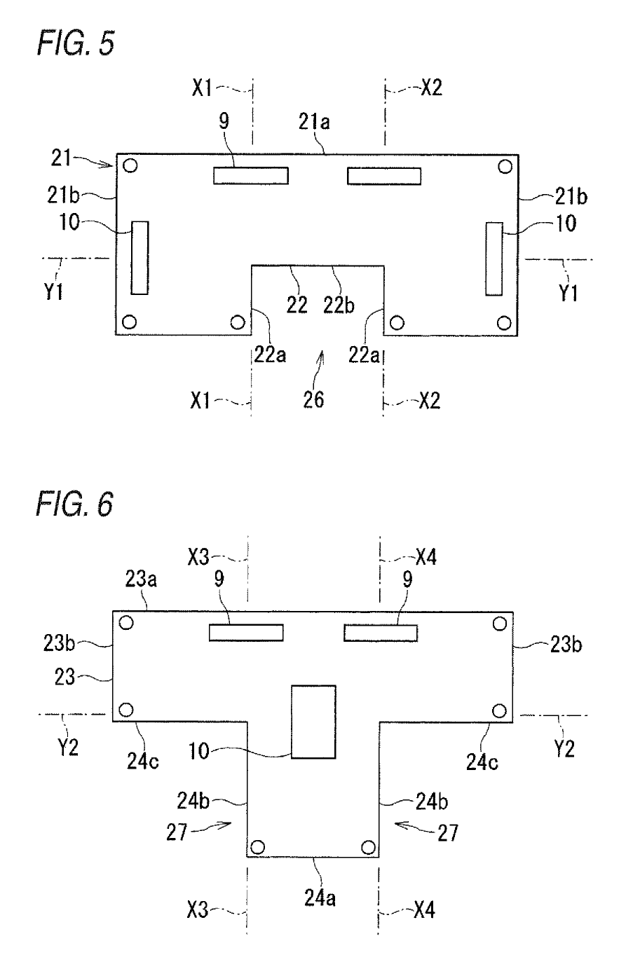

For example, like a printed circuit board 21 shown in FIG. 5, a polygonal shape having a recess part 22 provided by removing one of long edges of the printed circuit board 21 having long edges 21a and short edges 21b as a rectangle can also be applied. That is, in the structure, a bending stress concentrates on the straight line directions of the portions where the length defined by the long edge 21a and the board width defined by the short edge 21b differ, namely, X1-X1 line direction, X2-X2 line direction, and Y1-Y1 line direction, but the connectors 9, the module 10, and the like of the electronic components are placed on the lines on which a stress concentrates, so that advantages similar to those of the embodiment described above can be provided.

Even in the printed circuit board 21 shown in FIG. 5, it can be said that first edges 22a and a second edge 22b forming the recess part 22 form a cutout portion 26. The connectors 9 are provided at the positions crossing the line X1-X1 and the line X2-X2 defined by the first edges 22a forming the cutout portion 26. Likewise, the module 10 is provided at the position crossing the line Y1-Y1 defined by the second edge 22b forming the cutout portion 26.

Like a printed circuit board 23 shown in FIG. 6, a polygonal shape having a convex part 24 shaped like a rectangle on one long edge of the printed circuit board 23 having a long edge 23a and a short edge 23b can also be applied. That is, in the structure, a bending stress concentrates on the straight line directions of the portions where the length defined by the long edge 23a and the board width defined by the short edge 23b differ, namely, X3-X3 line direction, X4-X4 line direction, and Y2-Y2 line direction, but the connectors 9, the module 10, and the like of the electronic components are placed on the lines on which a stress concentrates, so that advantages similar to those of the embodiment described above can be provided.

In the printed circuit board 23 shown in FIG. 6, a first edge 24a and second edges 24b form the convex part 24. It can also be said that the second edges 24b and third edges 24c form cutout portions 27. The connectors 9 are provided at the positions crossing the line X3-X3 and the line X4-X4 defined by the second edges 24b forming the cutout portions 27. Likewise, the module 10 is provided at the position crossing the line Y2-Y2 defined by the third edges 24c forming the cutout portions 27.

As described above, according to the embodiment of the invention, there can be provided an electronic apparatus for making it possible to reinforce a printed circuit board without adding a dedicated reinforcement member onto the printed circuit board.

It is to be understood that the invention is not limited to the above-described specific embodiment thereof and various modifications may be made without departing from the spirit and the scope of the invention.

What is claimed is:

1. An electronic apparatus comprising:
a polygonal printed circuit board provided with a cutout portion at least in a part, the cutout portion defined by at least a first edge and a second edge; and
a first electronic component mounted on the printed circuit board;
wherein the first electronic component is mounted at a position crossing a line defined by the first edge on the printed circuit board.

2. The apparatus according to claim 1 further comprising a second electronic component mounted at a position crossing a line defined by the second edge on the printed circuit board.

3. The apparatus according to claim 1, wherein the first electronic component includes a connector or a module.

4. The apparatus according to claim 2, wherein the second electronic component includes a connector or a module.

5. The apparatus according to claim 3 further comprising a spacer, wherein the module includes a module board, and wherein the spacer is interposed between the printed circuit board and a module board for connecting and fixing the module board to the printed circuit board.

6. The apparatus according to claim 4 further comprising a spacer, wherein the module includes a module board, and wherein the spacer is interposed between the printed circuit board and a module board for connecting and fixing the module board to the printed circuit board.
